(19) United States
(12) Patent Application Publication
(10) Pub. No.: US 2010/0195000 A1
(43) Pub. Date: Aug. 5, 2010

(54) CONTROL METHOD OF FREQUENCY VARIABLE FILTER CIRCUIT AND RECEIVING APPARATUS

(76) Inventor: Akihisa Iikura, Miyagi-ken (JP)

Correspondence Address: BRINKS HOFER GILSON & LIONE, P.O. BOX 10395, CHICAGO, IL, 60610, US

(21) Appl. No.: 12/684,407

(22) Filed: Jan. 8, 2010

(30) Foreign Application Priority Data
Jan. 30, 2009 (JP) 2009-019606

(51) Int. Cl. H04N 5/50; H03H 7/01

(52) U.S. Cl. 348/731; 333/176; 348/E05.097

(57) ABSTRACT

Provided is a control method of a frequency variable filter circuit including a resonant circuit of an inductor and a variable capacitance unit, the method including: determining a center frequency of the frequency variable filter circuit, wherein the variable capacitance unit includes a capacitor bank, a capacitance value Y of the capacitor bank is expressed by an equation below with respect to an assigned frequency, and the center frequency thereof is determined by deciding coefficients α, β, A, B and C.

Y=A×(α−X)ⁿ+B×(α−X)⁽ⁿ⁻¹⁾+C×(α−X)⁽ⁿ⁻²⁾+ . . . +β
(where, X is the assigned frequency, Y is the capacitance value of the capacitor bank, α is an offset frequency coefficient, β is a correction coefficient for correcting frequency shift, A, B and C are correction coefficients for correcting frequency shift of the center frequency with respect to the assigned frequency, and n is a positive integer equal to or larger than 2)

### CROSS REFERENCE TO RELATED APPLICATION

The present invention claims the benefit of Japanese Patent Application JP 2009-019606 filed in the Japanese Patent Office on Jan. 30, 2009, the entire contents of which is incorporated herein by reference.

### BACKGROUND

1. Technical Field

The present invention relates to a control method of a frequency variable filter circuit used for a tuner or the like and a receiving apparatus.

2. Related Art

In a tuner used for a television receiver or the like, a filter circuit including a parallel resonant circuit is used. In the filter circuit, a capacitance value is adjusted, so that a filter center frequency can be adjusted to a filter center frequency corresponding to a desired reception frequency band. According to a frequency variable filter circuit of the related art, a capacitor bank is formed from a plurality of capacitors and a capacitance value of the capacitor bank is switched, so that a filter center frequency can be adjusted (e.g., Japanese Unexamined Patent Application Publication No. 2006-295483).

The frequency variable filter circuit includes a first oscillator that oscillates a signal corresponding to a desired reception frequency, a second oscillator that oscillates a signal used for the adjustment of a filter center frequency, primary and secondary tuning circuits provided with inductors and capacitor banks, an up/down counter that controls the on/off state of the inductor and the capacitor bank of the tuning circuits, a detection circuit that detects a signal output from the tuning circuits, and a controller that detects a detection signal output from the detection circuit and outputs an up/down signal.

If a signal is received, the signal corresponding to the desired reception frequency is oscillated from the first oscillator and the signal having a frequency the same as a frequency of the received signal is oscillated from the second oscillator. The received signal is converted to an IF signal by the oscillation signals from the first and second oscillators. The IF signal is converted to the detection signal by the detection circuit, and the detection signal is input to the controller. The controller outputs an up count signal or a down count signal to the up/down counter in response to the detection signal. The up/down counter switches capacitance values of the capacitor banks of the primary and secondary tuning circuits in response to the up/down count signals, thereby adjusting the filter center frequency. As described above, the capacitance values of the capacitor banks can be adjusted such that the filter center frequency corresponding to the desired reception frequency is obtained.

However, according to the frequency variable filter circuit disclosed in Japanese Unexamined Patent Application Publication No. 2006-295483, the oscillation circuit, a PLL circuit or the like for adjusting the filter center frequency are required, so that circuit miniaturization is difficult.

In this regard, if the capacitance value of the capacitor bank, which can be used for adjusting the filter center frequency corresponding to the desired reception frequency, can be calculated through an operation process, it is unnecessary to use the oscillation circuit, the PLL circuit or the like for adjusting the filter center frequency, so that circuit miniaturization can be achieved. In the case in which the capacitance value of the capacitor bank is calculated through the operation process, after a filter center frequency (hereinafter, referred to as an assigned frequency) which can be synchronized with the desired reception frequency is selected, the capacitance value of the capacitor bank corresponding to the assigned frequency is calculated and the assigned frequency is adjusted using the calculated capacitance value of the capacitor bank, so that the desired reception frequency can be received.

However, according to the frequency variable filter circuit, in the case in which the capacitance value of the capacitor bank is calculated through the operation process and a control using the filter center frequency corresponding to the assigned frequency is performed, since the relation between the capacitance value of the capacitor bank and the filter center frequency does not become linear, an operation process using a complicated function is necessary. In detail, a relation of an exponential expressed by an equation below is established therebetween, and an advanced operation process is required to calculate the capacitance value of the capacitor bank corresponding to the assigned frequency, so that a load of the operation process may become heavy. Further, since correction coefficients “a” to “e” of the equation below have a wide numerical value including a decimal, a digital operation is difficult and the capacity of a memory preserving the correction coefficients “a” to “e” may be increased.

Y=INT[10^{a-b×X+c/d×50}]−e Equation

In Equation, the Y denotes the capacitance value of the capacitor bank, the X denotes the assigned frequency, and the “a” to “e” denote correction coefficients (numerical width: 0.01 to 1).

### SUMMARY

According to an aspect of the disclosure, there is provided a control method of a frequency variable filter circuit including a resonant circuit of an inductor and a variable capacitance unit, the control method including: determining a center frequency of the frequency variable filter circuit. The variable capacitance unit includes a capacitor bank, a capacitance value Y of the capacitor bank is expressed by an equation below with respect to an assigned frequency, and the center frequency of the frequency variable filter circuit is determined by deciding coefficients α, β, A, B and C.

Y=A×(α−X)ⁿ+B×(α−X)⁽ⁿ⁻¹⁾+C×(α−X)⁽ⁿ⁻²⁾+ . . . +β

(where, the X is the assigned frequency, the Y is the capacitance value of the capacitor bank, the α is an offset frequency coefficient, the β is a correction coefficient for correcting a frequency shift with respect to an upper limit frequency or a lower limit frequency of a cover range, the A, B and C are correction coefficients for correcting a frequency shift of the center frequency with respect to the assigned frequency, and the n is a positive integer equal to or larger than 2)

According to the control method, a capacitor bank capacitance value becoming a filter center frequency corresponding to a desired received signal can be calculated without using an exponential and a decimal, so that a capacitance value of the capacitor bank, which corresponds to a frequency of the received signal, can be calculated through a simple operation process.

According to another aspect of the disclosure, there is provided a receiving apparatus comprising: a frequency variable filter circuit including a resonant circuit of an inductor and a variable capacitance unit. The variable capacitance unit includes a capacitor bank, a capacitance value Y of the capacitor bank is expressed by an equation below with respect to an assigned frequency, and a center frequency of the frequency variable filter circuit is determined by deciding coefficients α, β, A, B and C.

Y=A×(α−X)ⁿ+B×(α−X)⁽ⁿ⁻¹⁾+C×(α−X)⁽ⁿ⁻²⁾+ . . . +β

(where, the X is the assigned frequency, the Y is the capacitance value of the capacitor bank, the α is an offset frequency coefficient, the β is a correction coefficient for correcting a frequency shift with respect to an upper limit frequency or a lower limit frequency of a cover range, the A, B and C are correction coefficients for correcting a frequency shift of the center frequency with respect to the assigned frequency, and the n is a positive integer equal to or larger than 2)

### BRIEF DESCRIPTION OF THE DRAWINGS

FIG. 1 is a schematic view showing a receiving apparatus according to an embodiment of the invention.

FIGS. 2A and 2B are graphs showing the correlation between a filter center frequency and a capacitor bank capacitance value according to an embodiment of the invention.

FIGS. 3A and 3B are graphs showing derivation of Equation (1) according to an embodiment of the invention.

FIGS. 4A and 4B are showing the concept using the coefficients α and β of Equation (1) according to an embodiment of the invention.

FIG. 4C is a graph showing the concept using the coefficients A, B and C of Equation (1) according to an embodiment of the invention.

FIG. 5 is a block diagram showing functions of a television tuner according to an embodiment.

### DESCRIPTION OF EXEMPLARY EMBODIMENTS

An exemplary embodiment of the invention will be described with reference to the accompanying drawings.

In the following description, an assigned frequency and a filter center frequency are selectively used as representation of a filter center frequency corresponding to a capacitance value of a capacitor bank. However, the assigned frequency and the filter center frequency are defined as follows. The assigned frequency denotes a filter center frequency assigned in response to a desired reception frequency, and the filter center frequency denotes an actual filter center frequency of a frequency variable filter circuit.

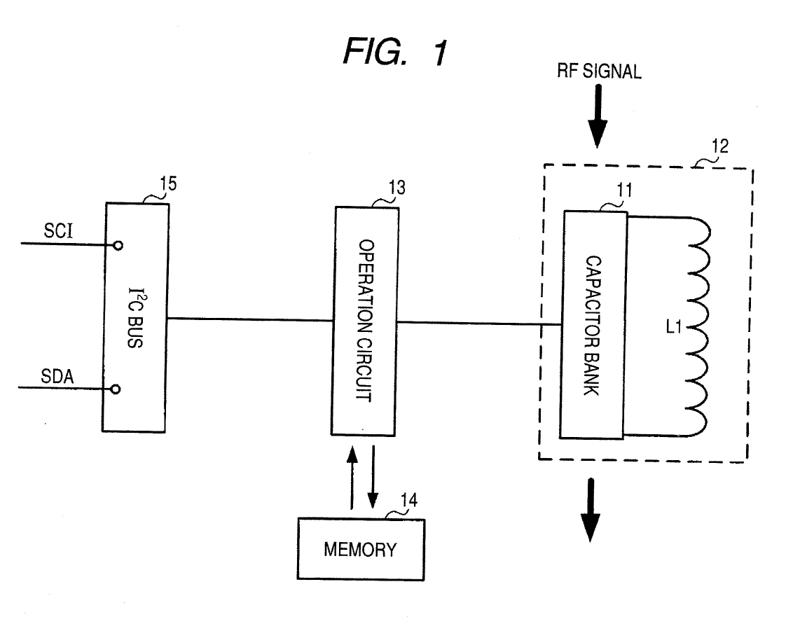

FIG. 1 is a schematic view showing an operation of a receiving apparatus according to the embodiment. The receiving apparatus according to the embodiment includes a frequency variable filter circuit 12, in which a capacitor bank 11 and an inductor L1 are connected in parallel to each other, an operation circuit 13 that calculates a capacitor bank capacitance value, a memory 14 that preserves data used for an operation in the operation circuit 13, and an I²C bus 15 through which an assigned frequency corresponding to a desired reception frequency is input from an exterior of an IC.

The assigned frequency corresponding to the desired reception frequency is input to the operation circuit 13 from an external controller (not shown) through the I²C bus 15 as a serial bus. The operation circuit 13 calculates the capacitor bank capacitance value, which corresponds to the assigned frequency, by using the assigned frequency and the data in the memory 14. The capacitor bank capacitance value calculated by the operation circuit 13 is output to the frequency variable filter circuit 12, so that the capacitance value of the capacitor bank 11 is adjusted based on the calculated capacitor bank capacitance value. In the embodiment, frequency data obtained in a PLL circuit can be used as the assigned frequency.

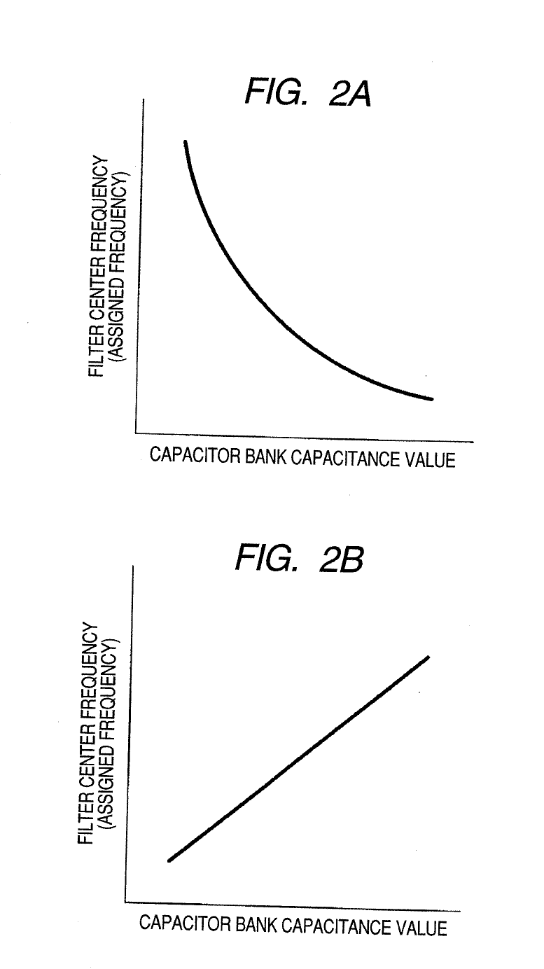

Next, the concept of the operation process in the operation circuit 13 will be described with reference to FIGS. 2A and 2B. FIG. 2A is a graph showing the correlation between the filter center frequency (assigned frequency) and the capacitor bank capacitance value. In the frequency variable filter circuit, as shown in FIGS. 2A and 2B, the correlation between the filter center frequency (assigned frequency) and the capacitor bank capacitance value is indicated by an exponential curve. Thus, in order to calculate the capacitor bank capacitance value corresponding to the filter center frequency (assigned frequency), an operation process using an exponential is required.

Meanwhile, FIG. 2B is a schematic graph showing the correlation between the assigned frequency (filter center frequency) and the capacitor bank capacitance value using an operation process in the embodiment. According to the embodiment, the curved correlation between the assigned frequency (filter center frequency) and the capacitor bank capacitance value as shown in FIG. 2A is calculated using an equation of high order as expressed by Equation (1) below, so that the curved correlation is converted to a linear correlation. In the operation, the assigned frequency and the coefficients α, β, A, B and C preserved in the memory are used, so that the capacitor bank capacitance value corresponding to the assigned frequency can be calculated using only four arithmetic operations without performing a complicated operation including an exponential, a decimal or the like.

Y=A×(α−X)ⁿ+B×(α−X)⁽ⁿ⁻¹⁾+C×(α−X)⁽ⁿ⁻²⁾+ . . . +β Equation (1)

In Equation (1), the X is the assigned frequency, the Y is the capacitance value of the capacitor bank, the α is an offset frequency coefficient, the β is a correction coefficient for correcting a frequency shift with respect to an upper limit frequency or a lower limit frequency of a cover range, the A, B and C are correction coefficients for correcting a frequency shift of the center frequency with respect to the assigned frequency, and the n is a positive integer equal to or larger than 2.

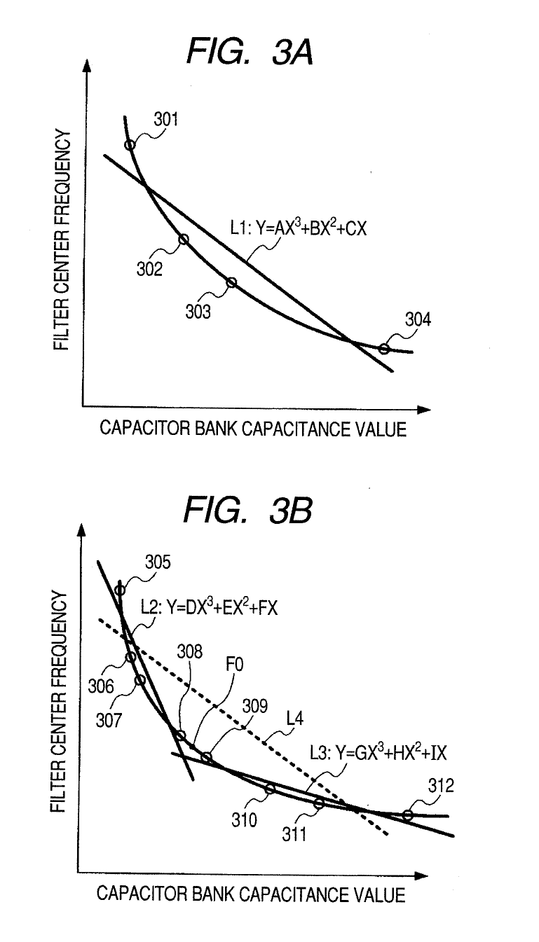

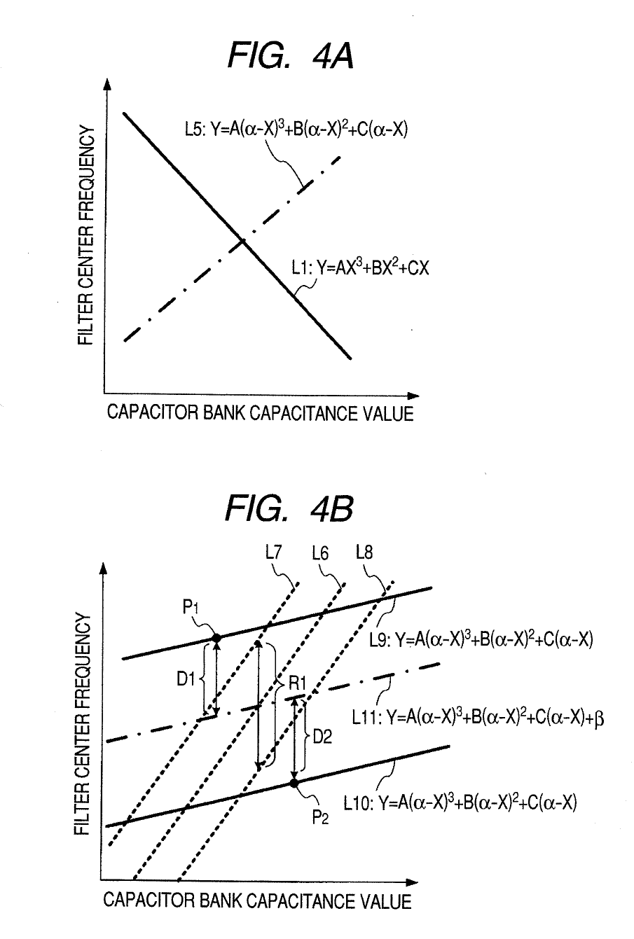

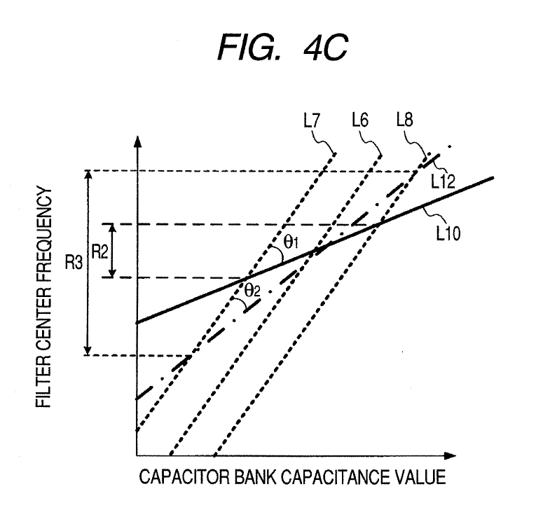

Hereinafter, the concept of deriving Equation (1) will be described with reference to FIGS. 3A and 3B and FIGS. 4A to 4C. FIGS. 3A and 3B are graphs showing the concept of deriving the equation of high order expressed by Equation (1), FIGS. 4A and 4B are graphs showing the concept using the coefficients α and β, and FIG. 4C is a graph showing the concept using the coefficients A, B and C.

According to the embodiment, the correlation between the assigned frequency and the capacitor bank capacitance value is made linear by a mathematic method such as a polynomial interpolation. FIG. 3A is an example in which the curve indicating the correlation between the filter center frequency and the capacitor bank capacitance value is converted into a solid line L1. In such a case, four points from white circles 301 to 304 on the curve are calculated and the relation between the four white circles 301 to 304 is made linear, so that the solid line L1 as an equation of high order can be derived. In such a case, the solid line L1 is a cubic equation.

FIG. 3B is an example in which eight points from white circles 305 to 312 on the curve are converted into two straight lines by using an inflection point F0. In such a case, the four points from white circles 305 to 308, which have a filter center frequency larger than that of the inflection point F0, are converted into an equation of high order as a solid line L2, and the four points from white circles 309 to 312, which have a filter center frequency smaller than that of the inflection point F0, are converted into an equation of high order as a solid line L3. In the operation process, in the area where the filter center frequency is larger than that of the inflection point F0, the operation process is performed using the equation of high order of the solid line L2. In the area where the filter center frequency is smaller than that of the inflection point F0, the operation process is performed using the equation of high order of the solid line L3. In such a case, the solid lines L2 and L3 are cubic equations.

In the case of FIG. 3B, the eight points can be converted into a dotted line L4 as one equation (seventh order equation) of high order. However, the curve is converted into two or more straight lines as shown in FIG. 3B, so that the order of an equation of high order used for the operation can be reduced. Thus, the operation load can be reduced, and errors can be prevented, as compared with the case in which the curve is converted into one straight line. In particular, when the curve, which represents the correlation between the filter center frequency and the capacitor bank capacitance value, has a high curvature, an operation is performed using two or more equations of high order, so that the operation load can be reduced and the operation accuracy can be improved.

In this way, according to the embodiment, the correlation of the capacitor bank capacitance value corresponding to the filter center frequency is derived as a linear equation of n^{th} order.

The solid line L1 of FIG. 4A is an example in which the correlation between the filter center frequency and the capacitor bank capacitance value is made linear through the process as shown in FIG. 3A. In such a case, the solid line L1 denotes an equation of high order in which the capacitor bank capacitance value is reduced as the filter center frequency is increased. Meanwhile, a dashed dotted line L5 of FIG. 4A is an example in which the slope of the straight line is inverted by introducing the offset correction coefficient α to the function of the solid line L1. In such a case, in the operation, the capacitor bank capacitance value is increased as the filter center frequency is increased, so that the load of the operation process can be reduced. As described above, according to the embodiment, the correlation between the assigned frequency and the capacitor bank capacitance value is inverted by introducing the offset correction coefficient α, so that the load of the operation process can be reduced.

FIG. 4B is a graph showing the concept using the tuning frequency range and the coefficient β of the frequency variable filter circuit. According to the embodiment, an upper limit value and a lower limit value of a tunable frequency exist with respect to a predetermined filter center frequency. When the filter center frequency varies along a straight line L6 of FIG. 4B, an upper limit value of a tunable frequency band is shown by a dotted line L7, and a lower limit value of the tunable frequency band is shown by a dotted line L8. Thus, the range between the dotted lines L7 and L8 as shown in an arrow R1 corresponds to the tuning frequency range of the frequency variable filter circuit.

The tuning frequency range of the frequency variable filter circuit varies depending on variation of the internal capacitance of the frequency variable filter circuit or variation of the performance of the inductor, and an error occurs in each frequency variable filter circuit. In this regard, in the actual frequency variable filter circuit, a cover range of a filter is changed in response to a frequency not being constant as shown in the arrow R1.

Further, according to the embodiment, the correlation between the filter center frequency and the capacitor bank capacitance value is made linear through the operation process, so that an error occurs between the assigned frequency used for the operation process and an actual filter center frequency adjusted after being calculated through the operation process. The error results from the difference of the distance and the slope between the curve before the operation process and the straight line after the operation process in each frequency.

Solid lines L9 and L10 of FIG. 4B show filter center frequencies and capacitor bank capacitance values adjusted through the operation process. In such a case, filter center frequencies adjusted through the operation process using the assigned frequency has numerical values on the solid lines L9 and L10. Thus, a point P1 on the solid line L9 and a point P2 on the solid line L10 deviate from the cover range R1 of the filter. In such a case, the coefficient β corresponding to an intercept of an operation equation is added to an operation equation of the solid line L9 and an operation equation of the solid line L10 so that the point P1 and the point P2 are shifted by D1 or D2. Consequently, the point P1 and the point P2 can be adjusted in the tuning frequency range through the operation process.

FIG. 4C is a graph showing the concept using the coefficients A, B and C. According to the embodiment, the cover range of the filter varies depending on the above-described variation of the performance of the capacitor and the inductor. The solid line L10 of FIG. 4C denotes the solid line L10 of FIG. 4B. In such a case, the cover range of the filter corresponds to the range of an arrow R2. Meanwhile, in relation to an equation of high order, numerical values of the coefficients A, B and C are adjusted, so that the slope θ1 of the operation equation can be changed. In such a case, the coefficients A, B and C of the equation of high order represented by the solid line L10 are adjusted to obtain the slope θ2 as shown in a dashed dotted line L12, so that the cover range of the filter can be expanded up to the range indicated by an arrow R3. According to the embodiment as described above, the coefficients α, β, A, B and C are used, so that the tuning frequency range and the cover range of the filter of the frequency variable filter circuit can be expanded.

Further, according to the embodiment, at least one of the coefficients α, β, A, B and C is determined through the adjustment process, so that remaining coefficients can be calculated using a predetermined constant number. In such a case, particularly, the coefficients A, B or the like, which have a large order of an equation of high order exerting a significant influence on an operation, are determined through the adjustment process, so that the operation load can be reduced. In addition, according to the embodiment, data of the coefficients α, β, A, B and C can be preserved in the memory and then used.

Moreover, according to the embodiment, the correlation between the filter center frequency and the capacitor bank capacitance value is made linear, so that the variation of the filter center frequency and the adjustment amount of the capacitor bank capacitance value are regularly changed over the wide range of the filter center frequency. Thus, a small difference occurs between the coefficients α, β, A, B and C, which are used for correction when the assigned frequency has been changed by a constant value in the area having a high filter center frequency, and the coefficients α, β, A, B and C, which are used for correction when the assigned frequency has been changed by a constant value in the area having a low filter center frequency, so that a numerical width of the coefficients used for the correction can be reduced. Meanwhile, when the correlation between the filter center frequency and the capacitor bank capacitance value is indicated by the curve, since the adjustment amount of the filter center frequency when the assigned frequency has been changed by a constant value in the area having a high filter center frequency is significantly different from the adjustment amount of the filter center frequency when the assigned frequency has been changed by a constant value in the area having a low filter center frequency, it is necessary to expand the numerical width of the coefficients used for the correction. Thus, according to the control method of the frequency variable filter circuit of the embodiment, the data amount of the coefficients preserved in the memory can be further reduced.

As described above, according to the embodiment, the correlation between the filter center frequency and the capacitor bank capacitance value is made linear through the operation process, so that it is possible to control the frequency variable filter circuit through a simple operation process.

Further, according to the embodiment, it is unnecessary to use a PLL circuit or an oscillator for frequency adjustment. In addition, an operation process can be performed through four arithmetic operations using only an integer without using an exponential and a decimal, so that calculation using not only an analog operation circuit but also a digital operation circuit is possible. Consequently, the circuit size can be reduced.

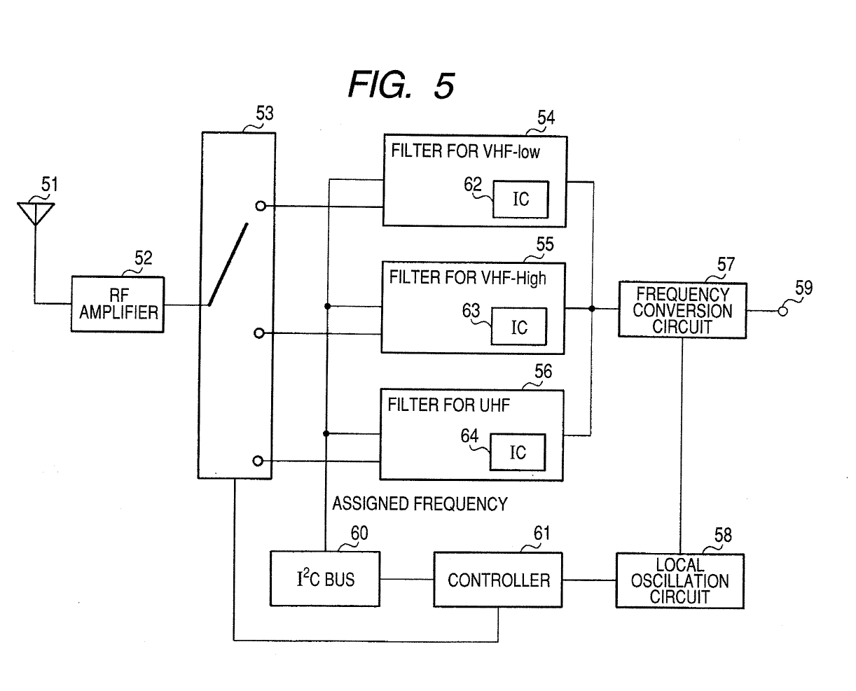

The control method of the frequency variable filter circuit as described above can be used for tuning circuits of various receiving apparatuses such as television tuners. Hereinafter, the television tuner according to the embodiment will be described with reference to FIG. 5.

FIG. 5 is a block diagram showing functions of the television tuner according to the embodiment. An input terminal of an RF amplifier 52 is connected to an antenna 51, and an output terminal of the RF amplifier 52 is connected to a switching circuit 53. The switching circuit 53 is connected to a frequency variable filter circuit 54 for VHF-Low, a frequency variable filter circuit 55 for VHF-High, and a frequency variable filter circuit 56 for UHF (hereinafter, referred to as frequency variable filter circuits 54 to 56). Output terminals of the frequency variable filter circuits 54 to 56 are connected to a frequency conversion circuit 57, and a local oscillation circuit 58 is connected to the frequency conversion circuit 57. An output terminal of the frequency conversion circuit 57 is connected to an output terminal 59 of the tuner. A controller 61 is connected to the frequency variable filter circuits 54 to 56 through an I²C bus 60. The switching circuit 53 and the local oscillation circuit 58 are connected to the controller 61.

Next, an operation of the television tuner according to the embodiment when a television broadcasting signal of a frequency band is received will be described. After the television broadcasting signal received in the antennal 51 is amplified by the RF amplifier 52, the amplified signal is input to the switching circuit 53. The switching circuit 53 is switched to be connected to the frequency variable filter circuit 54, 55 or 56 by the controller 61 according to a desired reception frequency band, so that the received signal is input to any one of the frequency variable filter circuits 54 to 56. An assigned frequency corresponding to a desired reception frequency is input to an IC 62 of the frequency variable filter circuit 54, an IC 63 of the frequency variable filter circuit 55, and an IC 64 of the frequency variable filter circuit 56 from the controller 61 through the I²C bus 60, so that a capacitor bank capacitance value corresponding to the assigned frequency is calculated and a filter center frequency is adjusted. The received signal filter-processed by any one of the frequency variable filter circuits 54 to 56 is input to the frequency conversion circuit 57. After the received signal input to the frequency conversion circuit 57 is mixed with an oscillation signal from the local oscillation circuit 58, a signal of the desired reception frequency band is extracted and output to a circuit next to the output terminal 59. The oscillation frequency of the oscillation circuit 58 is controlled by the controller 61.

Next, an operation process in the IC 62 of the frequency variable filter circuit 54, the IC 63 of the frequency variable filter circuit 55, and the IC 64 of the frequency variable filter circuit 56 will be described. In the television tuner according to the embodiment, the capacitor bank capacitance value corresponding to the assigned frequency is calculated using equations of high order expressed by Equations (2) to (6) below. Equation (2) is used for reception of a signal of a VHF-Low frequency band, Equations (3) and (4) are used for reception of a signal of a VHF-High frequency band, and Equations (5) and (6) are used for reception of a signal of a UHF frequency band. Switching from Equation (3) to Equation (4) is performed by setting an inflection point F1 in the VHF-High frequency band. Further, switching from Equation (5) to Equation (6) is performed by setting an inflection point F2 in the UHF frequency band. Equations (2) to (6) below are obtained by converting Equation (1) above into an Equation for the television tuner.

Y1=INT[{A×(α−X)³−B×(α−X)²}/1000]+C×(α−X)−D Equation (2)

Y2=INT[{A×(α−X)⁴−(B×10)×(α−X)³+(C×1000)×(α−X)²}1/10000 000]—D×(α−X)+E Equation (3)

Y3=INT[{A×(α−X)³−(B×10)×(α−X)²}/10000]−C×(α−X)+D Equation (4)

Y4=INT[{A×(α−X)³−B×(α−X)²}/100000000]+INT[C×(α−X)/100 0]−D Equation (5)

Y5=INT[{A×(α−X)³−(B×100)×(α−X)²}/1000000]+C×(α−X)−D Equation (6)

In Equations (2) to (6), the X is the assigned frequency, the Y is the capacitance value of the capacitor bank, the α is an offset frequency coefficient, and the A, B, C or the like are correction coefficients.

In Equations (2) to (6), terms A, B and C having a large order are divided by 10000000, so that a load of an operation process is reduced. For example, when the data amount is data of 10 bits or the like, if division is performed as it is, the numerical value is doubled, and the number of registers for data retention is increased. In this regard, the data is divided by a numerical value of a predetermined level or more, so that the data retention amount is reduced. Further, a calculation result of a lower 7 bit is deleted. In the embodiment, since a large division circuit of 1/10000000 is provided and operation results of a lower bit are not of concern, the operation results are deleted, so that the load of the operation process is reduced.

Equations (2) to (6) and the correction coefficients α, β, A, B and C are preserved in memories of the ICs 62 to 64, and used in an operation circuit according to the operation process. At least one of the correction coefficients α, β, A, B and C is determined through an adjustment process and stored in the memory. When the operation process is performed, the frequency variable filter circuit can be controlled using the coefficient stored in the memory.

Further, according to the embodiment, the operation process can be performed using at least two of the coefficients A, B, C and D used for Equations (2) to (6). The number of the coefficients used is increased, the load of the operation process can be reduced.

It should be understood by those skilled in the art that various modifications, combinations, sub-combinations and alterations may occur depending on design requirements and other factors insofar as they are within the scope of the appended claims of the equivalents thereof.

The invention can be applied to apparatus having various frequency variable filter circuits such as a television tuner.

It should be understood by those skilled in the art that various modifications, combinations, sub-combinations and alterations may occur depending on design requirements and other factors insofar as they are within the scope of the appended claims of the equivalents thereof.

What is claimed is:

1. A control method of a frequency variable filter circuit including a resonant circuit of an inductor and a variable capacitance unit, the control method comprising:
determining a center frequency of the frequency variable filter circuit,
wherein the variable capacitance unit includes a capacitor bank, a capacitance value Y of the capacitor bank is expressed by an equation below with respect to an assigned frequency, and the center frequency of the frequency variable filter circuit is determined by deciding coefficients α, β, A, B and C.
Y=A×(α−X)ⁿ+B×(α−X)⁽ⁿ⁻¹⁾+C×(α−X)⁽ⁿ⁻²⁾+ . . . +β
(where, the X is the assigned frequency, the Y is the capacitance value of the capacitor bank, the α is an offset frequency coefficient, the β is a correction coefficient for correcting a frequency shift with respect to an upper limit frequency or a lower limit frequency of a cover range, the A, B and C are correction coefficients for correcting a frequency shift of the center frequency with respect to the assigned frequency, and the n is a positive integer equal to or larger than 2)

2. The control method according to claim 1, wherein at least one of the coefficients α, β, A, B and C is determined through an adjustment process and the remaining coefficients have a predetermined constant number.

3. A receiving apparatus comprising:
a frequency variable filter circuit including a resonant circuit of an inductor and a variable capacitance unit,
wherein the variable capacitance unit includes a capacitor bank, a capacitance value Y of the capacitor bank is expressed by an equation below with respect to an assigned frequency, and a center frequency of the frequency variable filter circuit is determined by deciding coefficients α, β, A, B and C.
Y=A×(α−X)ⁿ+B×(α−X)⁽ⁿ⁻¹⁾+C×(α−X)⁽ⁿ⁻²⁾+ . . . +β
(where, the X is the assigned frequency, the Y is the capacitance value of the capacitor bank, the α is an offset frequency coefficient, the β is a correction coefficient for correcting a frequency shift with respect to an upper limit frequency or a lower limit frequency of a cover range, the A, B and C are correction coefficients for correcting a frequency shift of the center frequency with respect to the assigned frequency, and the n is a positive integer equal to or larger than 2)

4. The receiving apparatus according to claim 3, wherein at least one of the coefficients α, β, A, B and C is determined through an adjustment process and the receiving apparatus includes a memory that stores the coefficients.

5. The receiving apparatus according to claim 3, wherein the frequency variable filter circuit is provided for each frequency band, and the filter center frequency of the frequency variable filter circuit is adjusted according to the above equation.

6. The receiving apparatus according to claims 3, wherein a television broadcasting signal is received through the frequency variable filter circuit.
